(19) United States
(12) Patent Application Publication
(10) Pub. No.: US 2023/0221605 A1
(43) Pub. Date: Jul. 13, 2023

(54) SEMICONDUCTOR DEVICE

(71) Applicant: Sharp Display Technology Corporation, Kameyama City (JP)

(72) Inventors: Tetsuo KIKUCHI, Kameyama City (JP); Masahiko SUZUKI, Kameyama City (JP); Setsuji NISHIMIYA, Kameyama City (JP); Hitoshi TAKAHATA, Kameyama City (JP); Takuya WATANABE, Kameyama City (JP); Tohru DAITOH, Kameyama City (JP)

(21) Appl. No.: 18/096,056

(22) Filed: Jan. 12, 2023

Related U.S. Application Data
(60) Provisional application No. 63/299,218, filed on Jan. 13, 2022.

(51) Int. Cl. G02F 1/1362; H01L 27/12; H01L 29/786; G02F 1/1368; G02F 1/133; G09G 3/36

(52) U.S. Cl. CPC G02F 1/136286; H01L 27/1225; H01L 27/124; H01L 29/78648; H01L 29/7869; G02F 1/1368; G02F 1/13306; G09G 3/3648; G09G 3/3677; G09G 2310/0286; G09G 2310/08; G09G 2300/08; G09G 2310/0291

(57) ABSTRACT

A semiconductor device including a substrate, and a first circuit supported by the substrate and including a plurality of TFTs including a first TFT, wherein the first TFT includes a semiconductor layer, a lower gate electrode located on a side of the substrate of the semiconductor layer and overlapping a part of the semiconductor layer via a lower gate insulating layer, and an upper gate electrode located on a side opposite to the substrate of the semiconductor layer and overlapping a part of the semiconductor layer via an upper gate insulating layer, one of the lower gate electrode and the upper gate electrode is a first gate electrode and the other is a second gate electrode, a first signal is supplied to the first gate electrode, and a second signal different from the first signal is supplied to the second gate electrode, the first TFT has a threshold voltage between a high-level potential and a low-level potential of the first signal and between a high-level potential and a low-level potential of the second signal, and a period during which the first signal is at the high-level potential and a period during which the second signal is at the high-level potential do not overlap each other.

### CROSS-REFERENCE TO RELATED APPLICATIONS

This application claims the benefit of priority to U.S. Provisional Application No. 63/299218 filed on Jan. 13, 2022. The entire contents of the above-identified application are hereby incorporated by reference.

### BACKGROUND

### Technical Field

The disclosure relates to a semiconductor device.

An active matrix substrate used in a liquid crystal display device, an organic electroluminescence (EL) display device, or the like includes a display region including a plurality of pixels, and a region other than the display region (a non-display region or a frame region). The display region includes a switching element such as a Thin Film Transistor (hereinafter referred to as a “TFT”) for each of the pixels. Such a TFT is referred to as a “pixel TFT”. The active matrix substrate also includes a plurality of gate bus lines and a plurality of source bus lines, and a gate electrode of the pixel TFT is electrically connected to one corresponding gate bus line and a source electrode is electrically connected to one corresponding source bus line.

As such a pixel TFT, in the related art, a TFT including an amorphous silicon film serving as an active layer (hereinafter referred to as an “amorphous silicon TFT”) and a TFT including a crystalline silicon film such as a polycrystalline silicon film serving as an active layer (hereinafter referred to as a “crystalline silicon TFT”) have been widely used. It has been proposed in recent years to use an oxide semiconductor as a material of the active layer of a TFT in place of amorphous silicon and crystalline silicon. Such a TFT is referred to as an “oxide semiconductor TFT”. The oxide semiconductor has a higher mobility than amorphous silicon. Thus, the oxide semiconductor TFT can operate at a higher speed than the amorphous silicon TFT.

In the non-display region of the active matrix substrate, a peripheral circuit such as a drive circuit may be monolithically (integrally) formed. By monolithically forming the peripheral circuit, the non-display region is narrowed and the mounting process is simplified, resulting in cost reduction. For example, US 2020/0135132 A and JP 2019-74560 A disclose an active matrix substrate including a monolithically formed gate drive circuit (gate driver) that drives the plurality of gate bus lines.

### SUMMARY

Various display panels including smartphones, small tablets, and the like demand further narrowing of a non-display region. Thus, there is a demand for reducing an area (circuit area) required for a peripheral circuit in the non-display region. In addition, not only an active matrix substrate but also various semiconductor devices demand reducing the circuit area.

An embodiment of the disclosure is made in light of the circumstances described above, and an object of the disclosure is to provide a semiconductor device including a circuit including a plurality of TFTs and capable of reduction in circuit area.

The present specification discloses a semiconductor device according to the following items.

### Item 1

A semiconductor device including a substrate and a first circuit supported by the substrate, wherein the first circuit includes a plurality of TFTs including a first TFT, the first TFT includes a semiconductor layer, a lower gate electrode located on a side of the substrate of the semiconductor layer and overlapping a part of the semiconductor layer via a lower gate insulating layer, and an upper gate electrode located on a side opposite to the substrate of the semiconductor layer and overlapping a part of the semiconductor layer via an upper gate insulating layer, one of the lower gate electrode and the upper gate electrode is a first gate electrode and the other is a second gate electrode, a first signal is supplied to the first gate electrode, and a second signal different from the first signal is supplied to the second gate electrode, the first TFT has a threshold voltage at which the first TFT is switched on/off between a high-level potential and a low-level potential of the first signal and between a high-level potential and a low-level potential of the second signal, and a period during which the first signal is at the high-level potential and a period during which the second signal is at the high-level potential do not overlap each other.

### Item 2

The semiconductor device according to item 1 further includes a controller configured to supply at least one control signal to the first circuit, wherein the controller controls the first circuit such that periods during which the first signal and the second signal are at a high-level potential do not overlap each other.

### Item 3

The semiconductor device according to item 1 or 2, wherein the plurality of TFTs further include a second TFT, the second TFT includes a second semiconductor layer, a second lower gate electrode located on a side of the substrate of the second semiconductor layer and overlapping a part of the second semiconductor layer via the lower gate insulating layer, and a second upper gate electrode located on a side opposite to the substrate of the semiconductor layer and overlapping a part of the second semiconductor layer via the upper gate insulating layer, one of the second lower gate electrode and the second upper gate electrode is a third gate electrode and the other is a fourth gate electrode, a third signal is supplied to the third gate electrode, a fourth signal different from the third signal is supplied to the fourth gate electrode, and at least one of the third signal and the fourth signal is different from any of the first signal and the second signal, the second TFT has a threshold voltage at which the second TFT is switched on/off between a high-level potential and a low-level potential of the third signal and between a high-level potential and a low-level potential of the fourth signal, and a period during which the third signal is at the high-level potential and a period during which the fourth signal is at the high-level potential do not overlap each other.

### Item 4

The semiconductor device according to any one of items 1 to 3, wherein the semiconductor device includes a shift register including a plurality of bistable circuits connected in multiple stages, and at least one of the plurality of bistable circuits includes the first circuit.

### Item 5

The semiconductor device according to item 4, wherein one of the first signal and the second signal is a clear signal configured to initialize the at least one bistable circuit.

### Item 6

The semiconductor device according to item 4 or 5, wherein the plurality of bistable circuits include a first bistable circuit including the first circuit, and a second bistable circuit not including the first circuit, and the number of TFTs constituting the first bistable circuit is less than the number of TFTs constituting the second bistable circuit.

### Item 7

The semiconductor device according to any one of items 1 to 3 and 6 further including a plurality of source bus lines and a plurality of gate bus lines supported by the substrate, a plurality of pixel regions, each of which being arranged corresponding to one of the plurality of source bus lines and one of the plurality of gate bus lines, and a gate driver configured to selectively drive the plurality of gate bus lines, wherein the gate driver includes a shift register provided corresponding to the plurality of gate bus lines and including a plurality of bistable circuits connected in multiple stages to sequentially output pulses based on a plurality of gate clock signals having phases different from each other, at least the plurality of gate clock signals, a high-level power supply voltage signal, a low-level power supply voltage signal, and a clear signal that initializes each bistable circuit are input to each bistable circuit, and at least one of the plurality of bistable circuits includes the first circuit.

### Item 8

The semiconductor device according to item 7, wherein in the at least one bistable circuit, the low-level power supply voltage signal is supplied to a source electrode of the first TFT, a drain electrode of the first TFT is connected to a first node including an output end of the at least one bistable circuit, the clear signal is supplied to the first gate electrode, and the second gate electrode is connected to a node different from the first node.

### Item 9

The semiconductor device according to item 7, wherein in the at least one bistable circuit, the low-level power supply voltage signal is supplied to a source electrode of the first TFT, a drain electrode of the first TFT is connected to a first node including an output end of the at least one bistable circuit, the clear signal is supplied to the first gate electrode, and the second gate electrode is connected to a gate bus line corresponding to a bistable circuit in a stage subsequent to the at least one bistable circuit.

### Item 10

The semiconductor device according to item 7, wherein in the at least one bistable circuit, the low-level power supply voltage signal is supplied to a source electrode of the first TFT, a drain electrode of the first TFT is connected to a second node different from a first node including an output end of the at least one bistable circuit, the clear signal is supplied to the first gate electrode, and the second gate electrode is connected to the first node.

### Item 11

The semiconductor device according to item 7, wherein in the at least one bistable circuit, the low-level power supply voltage signal is supplied to a source electrode of the first TFT, a drain electrode of the first TFT is connected to a second node different from a first node including an output end of the at least one bistable circuit, the clear signal is supplied to the first gate electrode, and the second gate electrode is connected to a gate bus line corresponding to a bistable circuit in a stage preceding the at least one bistable circuit.

### Item 12

The semiconductor device according to any one of items 1 to 11, wherein the first TFT is an oxide semiconductor TFT having an oxide semiconductor layer as an active layer.

Item 13

The semiconductor device according to item 12, wherein the oxide semiconductor layer includes an In—Ga—Zn—O based semiconductor.

Item 14

The semiconductor device according to item 13, wherein the In—Ga—Zn—O based semiconductor includes a crystalline portion.

According to an embodiment of the disclosure, a semiconductor device including a circuit including a plurality of TFTs and capable of reduction in circuit area can be provided.

### BRIEF DESCRIPTION OF DRAWINGS

The disclosure will be described with reference to the accompanying drawings, wherein like numbers reference like elements.

FIG. 1A is a schematic plan view illustrating a part of a first circuit 10 in a semiconductor device of an embodiment according to the disclosure.

FIG. 1B is a cross-sectional view taken along a line Ib-Ib′ of the semiconductor device illustrated in FIG. 1A.

FIG. 2 is a schematic diagram illustrating waveforms of signals applied to a gate electrode of a first TFT 30.

FIG. 3 is a schematic plan view illustrating a liquid crystal display device 1000 including a semiconductor device (active matrix substrate) 100 of the embodiment.

FIG. 4 is a schematic diagram illustrating gate drivers GD.

FIG. 5A is a circuit diagram illustrating a basic unit circuit Uref(n) in the gate driver GD.

FIG. 5B is a signal waveform diagram for describing operations of the gate driver GD.

FIG. 6 is a circuit diagram illustrating a unit circuit Ua(n) in the gate driver GD.

FIG. 7 is a circuit diagram illustrating another unit circuit Ub(n) in the gate driver GD.

FIG. 8 is a circuit diagram illustrating yet another unit circuit Uc(n) in the gate driver GD.

FIG. 9 is a circuit diagram illustrating yet another unit circuit Ud(n) in the gate driver GD.

FIG. 10 is a circuit diagram illustrating yet another unit circuit Ue(n) in the gate driver GD.

FIG. 11A is a diagram illustrating a semiconductor device including a protection circuit PCref of a reference example.

FIG. 11B is a circuit diagram of a protection circuit PCref of the reference example.

FIG. 12 is a diagram illustrating an example of a protection circuit PC in a first modified example.

FIG. 13 is a diagram illustrating an example of a demultiplexer circuit DMXref of the reference example.

FIG. 14 is a diagram illustrating one four-terminal structure TFT 36 constituting a demultiplexer circuit in a second modified example.

FIG. 15 is a plan view illustrating a part of a circuit 90 of the reference example.

### DESCRIPTION OF EMBODIMENTS

### Embodiments

Hereinafter, an embodiment of a semiconductor device according to the disclosure will be described with reference to the drawings. In the present specification, it is sufficient that the “semiconductor device” is provided with a circuit supported by a substrate, and the semiconductor device widely includes circuit substrates, such as the active matrix substrate, various display devices, electronic devices, and the like.

The semiconductor device according to the present embodiment includes a substrate, and a circuit (herein after referred to as a “first circuit”) supported by the substrate and including a plurality of TFTs. The plurality of TFTs include at least one first TFT having a structure in which each of gate electrodes is provided on a respective one of a side of the substrate and a side opposite thereto of a semiconductor layer serving as an active layer. That is, the first TFT includes four terminals of two gate electrodes (gate terminals), a source electrode (source terminal), and a drain electrode (drain terminal). Such a TFT is referred to as a “four-terminal structure TFT”.

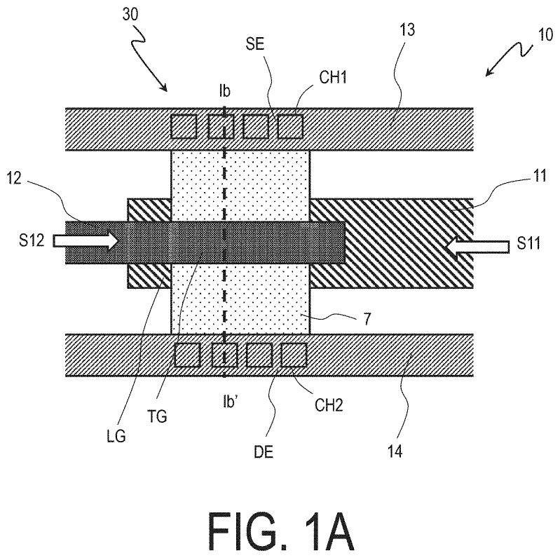

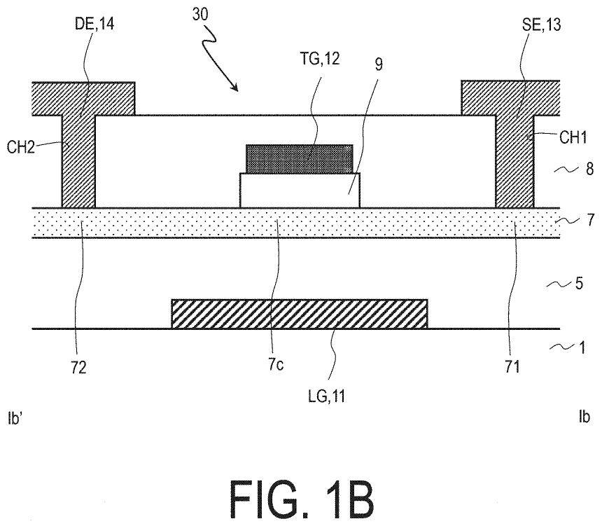

FIG. 1A is a schematic plan view illustrating a part of a first circuit 10 including a first TFT 30 in a semiconductor device according to the present embodiment, and FIG. 1B is a cross-sectional view taken along a line Ib-Ib′ illustrated in FIG. 1A, illustrating a cross-section of the first TFT 30 in a channel length direction.

The semiconductor device according to the present embodiment includes a substrate 1 and a first circuit 10 supported by the substrate 1. The first circuit 10 includes a plurality of TFTs including at least one first TFT 30, a plurality of wiring lines including a first wiring line 11, a second wiring line 12, a third wiring line 13, and a fourth wiring line 14. The first circuit 10 is, for example, one of a plurality of bistable circuits constituting a gate driver. Note that the first circuit 10 is not particularly limited. As described below, it can be applied to a diode ring, a demultiplexer circuit, or the like.

The first TFT 30 is the four-terminal structure TFT described above. Here, a configuration of the first TFT 30 will be described in a case where the first TFT 30 is an oxide semiconductor TFT.

As illustrated in FIG. 1B, the first TFT 30 includes a semiconductor layer 7, a lower gate electrode LG located between the semiconductor layer 7 and the substrate 1, a lower gate insulating layer 5 located between the lower gate electrode LG and the semiconductor layer 7, an upper gate electrode TG located on a side opposite to the substrate 1 of the semiconductor layer 7, an upper gate insulating layer 9 located between the upper gate electrode TG and the semiconductor layer 7, a source electrode SE, and a drain electrode DE.

The semiconductor layer 7 is, for example, an oxide semiconductor layer. The semiconductor layer 7 includes a channel region 7c and first and second regions 71 and 72 respectively located on both sides of the channel region 7c, when viewed from a normal direction of a main surface of the substrate 1. The first region 71 and the second region 72 are electrically connected to the source electrode SE and the drain electrode DE, respectively. The first region 71 and the second region 72 are low-resistive regions having specific resistance lower than that of the channel region 7c. The first region 71 and the second region 72 may be conductive regions.

The upper gate electrode TG at least partially overlaps the channel region 7c via the upper gate insulating layer 9, and the lower gate electrode LG at least partially overlaps the channel region 7c via the lower gate insulating layer 5, when viewed from the normal direction of the substrate 1. In this example, a part of the semiconductor layer 7 that overlaps the upper gate electrode TG is the channel region 7c, and the lower gate electrode LG is disposed to overlap the entire channel region 7c, when viewed from the normal direction of the substrate 1. The width of the lower gate electrode LG in the channel length direction may be larger than the width of the upper gate electrode TG in the channel length direction. In the example illustrated in FIG. 1A, the upper gate electrode TG and the lower gate electrode LG cross the semiconductor layer 7 in a channel width direction, when viewed from the normal direction of the substrate 1. A part of the upper gate electrode TG that overlaps the semiconductor layer 7 may be located inside an outer edge of the lower gate electrode LG, when viewed from the normal direction of the substrate 1.

The lower gate electrode LG and the upper gate electrode TG are electrically connected to the first wiring line 11 and the second wiring line 12, respectively. The lower gate electrode LG and the first wiring line 11 may be formed in the same layer (that is, from the same conductive film), and the upper gate electrode TG and the second wiring line 12 may be formed in the same layer. In this example, the lower gate electrode LG is a part of the first wiring line 11, and the upper gate electrode TG is a part of the second wiring line 12. In this case, a part of the first wiring line 11 that overlaps the semiconductor layer 7 when viewed from the normal direction of the substrate 1 is referred to as the lower gate electrode LG, and a part of the second wiring line 12 that overlaps the semiconductor layer 7 is referred to as the upper gate electrode TG.

The upper gate insulating layer 9 is so disposed as to cover a part (here, the channel region 7c) of the semiconductor layer 7 and to not cover the first region 71 and the second region 72, for example. The upper gate insulating layer 9 may be located only between the semiconductor layer 7 and the upper gate electrode TG. In this case, a side surface of the upper gate electrode TG may be aligned with a side surface of the upper gate insulating layer 9. Alternatively, the upper gate electrode TG may be disposed to cover only a part of an upper surface of the upper gate insulating layer 9. Although not illustrated, the upper gate insulating layer 9 may be disposed to cover the entirety of an upper surface of the semiconductor layer 7 other than the first region 71 and the second region 72.

The semiconductor layer 7, the upper gate insulating layer 9, and the upper gate electrode TG are covered by an interlayer insulating layer 8. At least one source opening CH1 that exposes the first region 71 and at least one drain opening CH2 that exposes the second region 72 are formed in the interlayer insulating layer 8. As illustrated in FIG. 1A, a plurality (here, four) of the source openings CH1 that expose the first region 71 may be formed separately from each other in the interlayer insulating layer 8. Similarly, a plurality (here, four) of the drain openings CH2 that expose the second region 72 may be formed separately from each other.

The source electrode SE is formed on the interlayer insulating layer 8 and inside the source opening CH1, and is connected to the first region 71 of the semiconductor layer 7 inside the source opening CH1. The drain electrode DE is formed on the interlayer insulating layer 8 and inside the drain opening CH2, and is connected to the second region 72 of the semiconductor layer 7 inside the drain opening CH2. In this example, the first region 71 is electrically connected to the third wiring line 13 constituting the first circuit 10 by the source electrode SE. The second region 72 is electrically connected to the fourth wiring line 14 constituting the first circuit 10 by the drain electrode DE. The source electrode SE, the drain electrode DE, the third wiring line 13, and the fourth wiring line 14 may be formed in the same layer (that is, from the same conductive film). In this example, the source electrode SE is a part of the third wiring line 13, and the drain electrode DE is a part of the fourth wiring line 14. In this case, a part of the third wiring line 13 that is connected to the semiconductor layer 7 is referred to as the source electrode SE, and a part of the fourth wiring line 14 that is connected to the semiconductor layer 7 is referred to as the drain electrode DE.

Various known conductive materials can be used as materials of the upper gate electrode TG, the lower gate electrode LG, the source electrode SE, and the drain electrode DE. Furthermore, various known insulating materials can be used as materials of the upper gate insulating layer 9, the lower gate insulating layer 5, and the interlayer insulating layer 8. When the semiconductor layer 7 is the oxide semiconductor layer, the lower gate insulating layer 5 and the upper gate insulating layer 9 may be, for example, silicon oxide layers. The interlayer insulating layer 8 may include a silicon nitride layer.

In the present embodiment, each of signals different from each other is supplied to a respective one of the upper gate electrode TG and the lower gate electrode LG of the first TFT 30. When one of the lower gate electrode LG and the upper gate electrode TG is referred to as a “first gate electrode”, the other is referred to as a “second gate electrode”, a first signal S11 is supplied to the first gate electrode (the lower gate electrode LG in the illustrated example) by the first wiring line 11, and a second signal S12 is supplied to the second gate electrode (the upper gate electrode TG in the illustrated example) by the second wiring line 12.

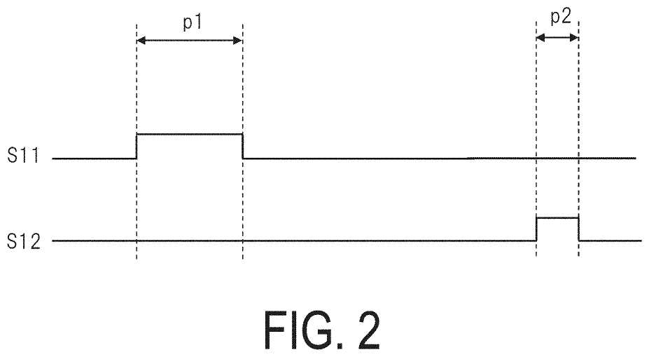

FIG. 2 is a schematic diagram illustrating waveforms of the first signal S11 and the second signal S12 applied to the first and second gate electrodes, respectively, of the first TFT 30.

As illustrated in FIG. 2, the first signal S11 and the second signal S12 respectively include a period at a high-level potential and a period at a low-level potential. In the present embodiment, a period p1 during which the first signal S11 is at the high-level potential and a period p2 during which the second signal S12 is at the high-level potential are configured to not overlap each other. The first TFT 30 has a threshold voltage Vth between the high-level potential and the low-level potential of the first signal S11 and between the high-level potential and the low-level potential of the second signal S12. The threshold voltage Vth is a gate-source voltage Vgs when the first TFT 30 is switched on/off. According to such a configuration, the first TFT 30 is in the on state by the first signal S11 in the period p1, and is in the on state by the second signal S12 in the period p2.

The structures of the first TFT 30 is not limited to the structures illustrated in the drawing. The source electrode SE and the drain electrode DE may be formed in separate layers. In this example, although the upper surface of the semiconductor layer 7 is in contact with the source electrode SE and the drain electrode DE (top contact structure), the lower surface of the semiconductor layer 7 may be in contact with the source electrode SE and/or the drain electrode DE (bottom contact structure). Furthermore, the first TFT 30 is not limited to the oxide semiconductor TFT, and may be an amorphous silicon TFT, a crystalline silicon TFT, or the like.

Although not illustrated, the semiconductor device of the present embodiment may further include a controller that supplies at least one control signal to the first circuit 10. The controller controls the first circuit 10 so that the periods p1 and p2, during which the first signal S11 and the second signal S12 are at the high-level potential, respectively, do not overlap each other. The controller may be connected to the first circuit 10, and need not be monolithically formed on the substrate 1. The controller may be mounted on the substrate 1, for example.

### Effect

According to the present embodiment, the first TFT 30 can be provided with a function of two different TFTs, and thus the number of TFTs can be reduced as compared to a conventional circuit. As a result, the circuit area can be reduced while having the same function as a conventional one.

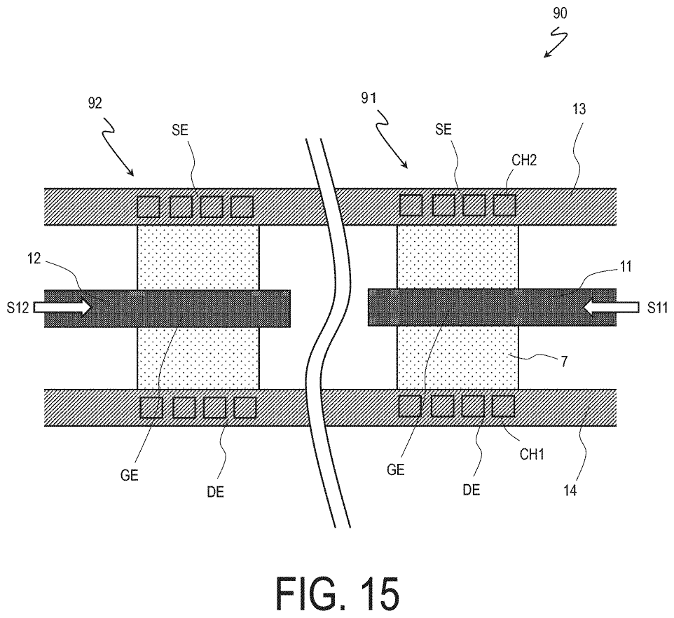

FIG. 15 is a plan view illustrating a part of a circuit 90 of a reference example. For clarity, the same reference numerals are attached to the same components as those in FIG. 1A. The circuit 90 of the reference example includes a plurality of TFTs including two TFTs 91 and 92. The TFTs 91 and 92 are, for example, three-terminal structure TFTs including one gate electrode GE (gate terminal), one source electrode SE (source terminal), and one drain electrode DE (drain terminal). In this example, the gate electrode GE is disposed above (on a side opposite to the substrate) the semiconductor layer 7 (top gate structure), but may be disposed between the semiconductor layer 7 and the substrate (bottom gate structure).

The TFT 91 includes the gate electrode GE, the source electrode SE, and the drain electrode DE electrically connected to the first wiring line 11, the third wiring line 13, and the fourth wiring line 14, respectively. The TFT 92 includes the gate electrode GE, the source electrode SE, and the drain electrode DE electrically connected to the second wiring line 12, the third wiring line 13, and the fourth wiring line 14, respectively. the first signal S11 is supplied to the gate electrode GE of the TFT 91 by the first wiring line 11, and the second signal S12 is supplied to the gate electrode GE of the TFT 92 by the second wiring line 12.

Accordingly, the TFT 91 is in the on state in the period p1 (FIG. 2) during which the first signal S11 is at the high-level potential, and a drain current flows between the source and the drain. The TFT 92 is in the on state in the period p2 (FIG. 2) during which the second signal S12 is at the high-level potential.

In contrast, in the first circuit 10 of the present embodiment, one four-terminal structure TFT (first TFT 30 illustrated in FIGS. 1A and 1B) having the functions of the TFTs 91 and 92 can be provided in place of the two TFTs 91 and 92. Thus, the circuit area can be reduced by one TFT.

In this manner, according to the present embodiment, two TFTs of the plurality of TFTs included in the circuit serving as a base can be replaced with one four-terminal structure TFT. Conditions of the two TFTs which can be replaced with the four-terminal structure TFT are as follows.

(A) A source side and a drain side of each of the two TFTs are connected to the same destination.

(B) Signals supplied to gates of the two TFTs are different from each other.

(C) A period during which the signal supplied to the gate of one TFT is at the high-level potential and a period during which the signal supplied to the gate of the other TFT is at the high-level potential do not overlap each other.

For example, the first TFT 30 having the four-terminal structure illustrated in FIGS. 1A and 1B can be used as the four-terminal structure TFT. In the first TFT 30, the lower gate insulating layer (for example, silicon oxide layer) 5 is preferably thicker than the upper gate insulating layer (for example, silicon oxide layer) 9 in order to ensure sufficient withstand voltage even at a step portion due to an edge of the lower gate electrode LG. In such a configuration, the mobility of the TFT is higher when a predetermined voltage is applied to the upper gate electrode TG to cause the on state than when a predetermined voltage is applied to the lower gate electrode LG to cause the on state. For this reason, it is preferable that a signal supplied to the gate of the TFT required to operate at a higher speed among the two replaceable TFTs satisfying the above conditions is supplied to the upper gate electrode TG of the first TFT30, and a signal supplied to the gate of the other TFT is supplied to the lower gate electrode LG of the first TFT30.

In a case where there is a plurality of combinations of the two TFTs replaceable with the four-terminal structure TFT (that is, satisfying the conditions (A) to (C) described above are) in the first circuit 10, the circuit area can be further effectively reduced by providing a plurality of the four-terminal structure TFTs.

As an example, the first circuit 10 may further include another TFT (referred to as a “second TFT”) having the four-terminal structure similar to the first TFT. A third signal and a fourth signal different from each other are applied to a respective one of two gate electrodes of the second TFT. At least one of the third signal and the fourth signal may be different from any of the first signal and the second signal, and one of the third signal and the fourth signal may be common to one of the first signal and the second signal. Similar to the first TFT, the second TFT has a threshold voltage between the high-level potential and the low-level potential of the third signal and between the high-level potential and the low-level potential of the fourth signal. A period during which the third signal is at the high-level potential and a period during which the fourth signal is at the high-level potential are configured to not overlap each other.

The present embodiment is suitably applied to, for example, an active matrix substrate including a monolithically formed gate driver. The gate driver includes a plurality of unit circuits connected in multiple stages, and each unit circuit includes the plurality of TFTs, and thus a ratio of the area of the TFTs occupying the gate driver may be high. According to the present embodiment, the area of each unit circuit can be reduced, and thus the area of the entire gate driver can be more effectively reduced.

### Overall Configuration of Active Matrix Substrate

Hereinafter, a more specific structure of the semiconductor device of the present embodiment will be described by taking an active matrix substrate as an example.

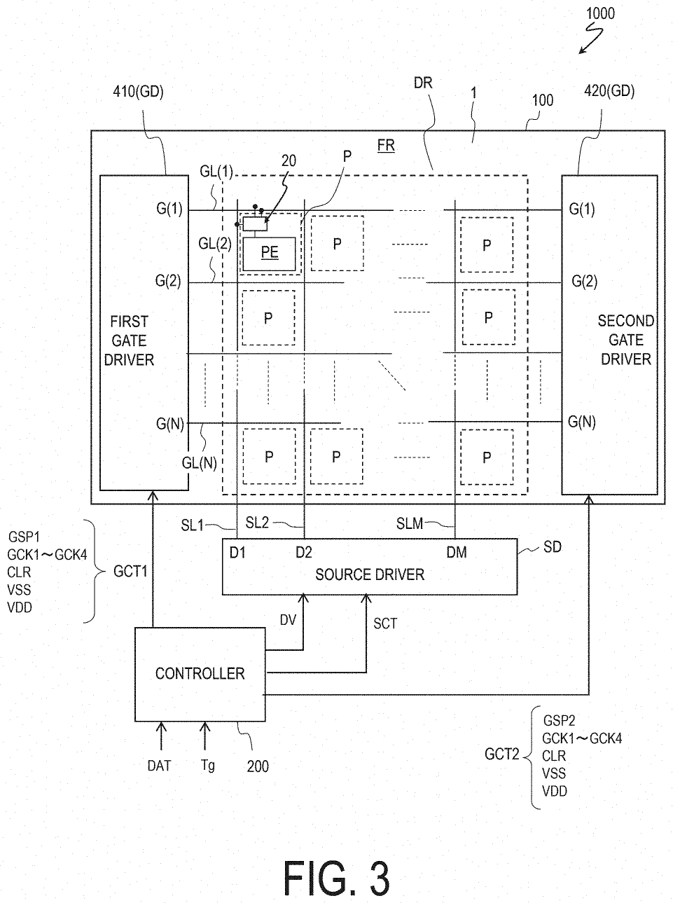

FIG. 3 is a block diagram illustrating an overall configuration of a liquid crystal display device 1000 including the active matrix substrate.

The liquid crystal display device 1000 includes an active matrix substrate 100, a controller 200, the source driver SD, a counter substrate (not illustrated), and a liquid crystal layer (not illustrated). The active matrix substrate 100 and the counter substrate face each other with the liquid crystal layer interposed therebetween to constitute a liquid crystal panel.

The active matrix substrate 100 includes a display region DR including a plurality of pixel regions P and a non-display region (also referred to as a “frame region”) FR located around the display region DR. The display region DR is defined by the plurality of pixel regions P. The plurality of pixel regions P are arrayed in a matrix shape including a plurality (here, N rows) of rows and a plurality (here, M columns) of columns. The pixel region P is a region corresponding to a pixel of the liquid crystal display device, and the pixel region P may simply be called the “pixel”. The non-display region FR is a region positioned in a periphery of the display region DR and does not contribute to display.

Provided in the display region DR are a plurality (here, M) of source bus lines SL1 to SLM extending in a column direction and a plurality (here, N) of gate bus lines GL(1) to GL(N) extending in a row direction. In the present specification, the source bus lines SL1 to SLM and the gate bus lines GL(1) to GL(N) may be collectively referred to as “source bus lines SL” and “gate bus lines GL”, respectively. Each of the plurality of pixel regions P is a region surrounded by a pair of the gate bus lines GL adjacent to each other and a pair of the source bus lines SL adjacent to each other, for example. In this example, the display region DR includes M×N pixel regions P.

In the display region DR, a thin film transistor (pixel TFT) 20 provided corresponding to each pixel region P, and a pixel electrode PE electrically connected to the pixel TFT 20 are disposed. A gate signal (scanning signal) and a data signal (display signal) are supplied from a corresponding gate bus line GL and a corresponding source bus line SL, respectively, to the pixel TFT 20. As the pixel TFT 20, the oxide semiconductor TFT having the oxide semiconductor layer as the active layer may be used, or other TFTs such as the amorphous silicon TFT and the crystalline silicon TFT may be used.

When a display mode of the liquid crystal display device 1000 is a transverse electrical field mode such as an FFS mode or an In-Plane Switching (IPS) mode, an electrode (common electrode) (not illustrated) that is common to the plurality of pixel regions P is provided in the active matrix substrate 100. When the display mode is a vertical electric field mode such as a Twisted Nematic (TN) mode or a Vertical Alignment (VA) mode, the common electrode is provided on the counter substrate side.

A peripheral circuit is provided in the non-display region FR. In this example, a gate driver GD that drives the gate bus lines GL is integrally (monolithically) formed as the peripheral circuit. As illustrated, the gate driver GD may include a first gate driver 410 and a second gate driver 420 respectively located on a respective one of both side (both ends in the row direction) of the display region DR. Note that the gate driver GD may be disposed only on one side of the display region DR. Although not illustrated, another peripheral circuit such as a demultiplexer circuit may be further monolithically formed in the non-display region FR.

The source driver SD for driving the source bus lines SL and the controller 200 are mounted in the non-display region FR.

The controller 200 receives an image signal DAT and a timing control signal Tg supplied from the outside, and outputs a digital video signal DV, a data side control signal SCT for controlling the operation of the source driver SD, and first and second scanning side control signals GCT1 and GCT2 for controlling the first and second gate drivers 410 and 420, respectively. The first scanning side control signal GCT1 includes a first gate start pulse signal GSP 1, first to fourth gate clock signals GCK1 to GCK4 having phases different from each other, a clear signal CLR, a high-level power supply voltage signal VDD, a low-level power supply voltage signal VSS, and the like. The second scanning side control signal GCT2 includes a second gate start pulse signal GSP2, the first to fourth gate clock signals GCK1 to GCK4, the clear signal CLR, the high-level power supply voltage signal VDD, the low-level power supply voltage signal VSS, and the like. In this example, the first and second gate drivers 410 and 420 operate by four-phase gate clock signals including the first to fourth gate clock signals GCK1 to GCK4.

The source driver SD applies data signals D1 to DM to the source bus lines SL1 to SLM, respectively, based on the digital video signal DV and the data side control signal SCT from the controller 200.

The first gate driver 410 is arranged on one end side of the gate bus lines GL(1) to GL(N), and applies scanning signals G(1) to G(N) to the one end sides of the gate bus lines GL(1) to GL(N), respectively, based on the first scanning side control signal GCT1 from the controller 200. On the other hand, the second gate driver 420 is arranged on the other end side of the gate bus lines GL(1) to GL(N), and applies the scanning signals G(1) to G(N) to the other end sides of the gate bus lines GL(1) to GL(N), respectively, based on the second scanning side control signal GCT2 from the controller 200. Accordingly, an active scanning signal is sequentially applied to the gate bus lines GL(1) to GL(N) from both ends in each frame period, and the application of the active scanning signal to each gate bus line GL(i) (i is an integer from 1 to N) is repeated with one frame period (one vertical scan period) as a cycle.

In the illustrated example, each of the scanning signals is applied to both ends of a respective one of the gate bus lines GL from the first and second gate drivers 410 and 420 (both-sides input system). Note that a method of applying the scanning signals to the gate bus lines GL is not particularly limited. For example, a one-side input system may be employed in which the scanning signals are applied from any one of the first and second gate drivers 410 and 420 to one sides (one end sides or the other end sides) of the gate bus lines GL. In the one-side input system, for example, the scanning signals may be applied from the first gate driver 410 to odd-numbered gate bus lines GL such as the gate bus line GL(1), the gate bus line GL(3), or the like, and the scanning signals may be applied from the second gate driver 420 to even-numbered gate bus lines GL such as the gate bus line GL(2), the gate bus line GL(4), or the like.

### Basic Configuration of Gate Driver

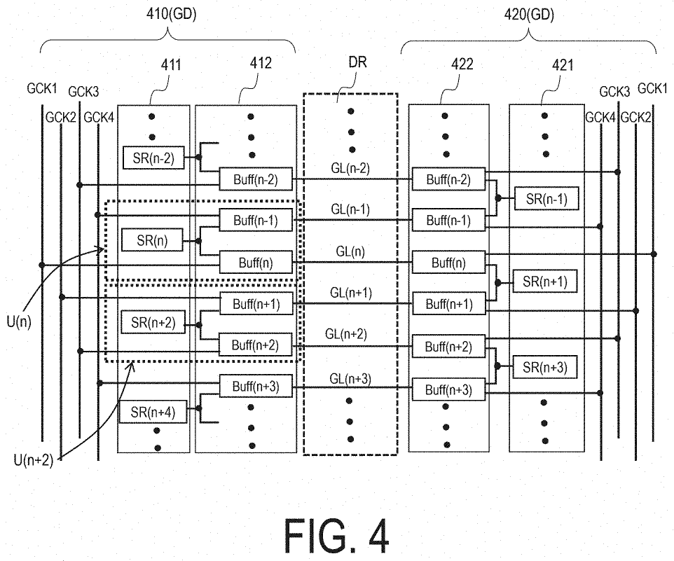

FIG. 4 is a schematic diagram of the first and second gate drivers 410 and 420 constituting the gate driver GD.

The gate driver GD includes N bistable circuits SR(1) to SR(N) associated with the plurality of gate bus lines GL(1) to GL(N), respectively.

The first gate driver 410 includes a first shift register 411 and a first output buffer unit 412. The second gate driver 420 includes a second shift register 421 and a second output buffer unit 422. The first shift register 411 has a configuration in which bistable circuits (SR(n−2), SR(n), SR(n+2), . . . ) selected alternately from the N bistable circuits SR(1) to SR(N) are connected in multiple stages. The second shift register 421 has a configuration in which bistable circuits (SR(n−1), SR(n+1), SR(n+3), . . . ) that are not included in the first shift register 411 among the N bistable circuits SR(1) to SR(N) are connected in multiple stages. Each of the first and second output buffer units 412 and 422 includes N buffer circuits Buff(1) to Buff(N). Each of buffer circuits Buff(1) to Buff(N) cyclically corresponds to the first to fourth gate clock signals GCK1 to GCK4.

A buffer circuit Buff(i) of the first gate driver 410 is connected to one end of each gate bus line GL(i) (i: an integer from 1 to N), and a buffer circuit Buff(i) of the second gate driver 420 is connected to the other end. Each of the buffer circuits Buff(1) to Buff(N) of the first and second gate drivers 410 and 420 applies scanning signals G(1) to G(N) to the gate bus lines GL(1) to GL(N), respectively.

Each bistable circuit SR(i) in the first and second shift registers 411 and 421 corresponds to two buffer circuits Buff(i−1) and Buff(i). Each bistable circuit SR(i) supplies the output signal thereof to these two buffer circuits Buff (i−1) and Buff(i).

Each buffer circuit Buff(i) receives the output signal of the corresponding bistable circuit SR(i) (or bistable circuit SR(i+1)) and a corresponding gate clock signal GCKk (k is any of 1 to 4), and generates a scanning signal G(i) to be applied to the gate bus line GL(i) from these signals. For example, in the first output buffer unit 412, the nth buffer circuit Buff(n) generates the scanning signal G(n) from the output signal of the bistable circuit SR(n) and the first gate clock signal GCK1, and applies the scanning signal G(n) to the gate bus line GL(n).

In the present specification, a circuit U(i) including one bistable circuit and a buffer circuit connected thereto is referred to as a “unit circuit”. In the both-sides input system, each unit circuit U(i) includes one bistable circuit SR(i) and two buffer circuits Buff(i−1) and Buff(i). In the example illustrated in FIG. 4, the one bistable circuit SR(n) and the two buffer circuits Buff(n−1) and Buff(n) constitute one unit circuit U(n), and one bistable circuit SR(n+2) and two buffer circuits Buff(n+1) and Buff(n+2) constitute one other unit circuit U(n+2). Note that in the one-side input system, for example, each unit circuit U(i) may include one bistable circuit SR(i) and one buffer circuit Buff(i).

### Basic Configuration and Operation of Unit Circuit U of Gate Driver GD

In describing the operation of the gate driver GD, first, a basic configuration of the unit circuit will be described. In the present specification, a unit circuit Uref having the basic configuration is referred to as a “basic unit circuit”. The unit circuit Uref including the nth bistable circuit SR(n) is referred to as a “basic unit circuit Uref(n)”.

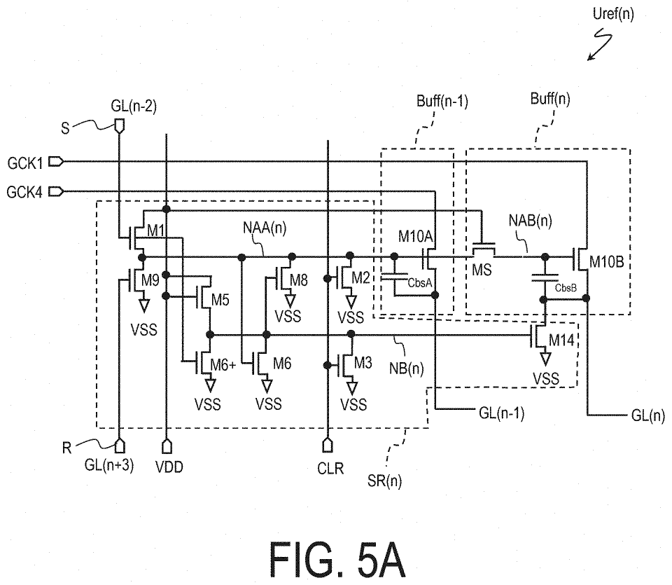

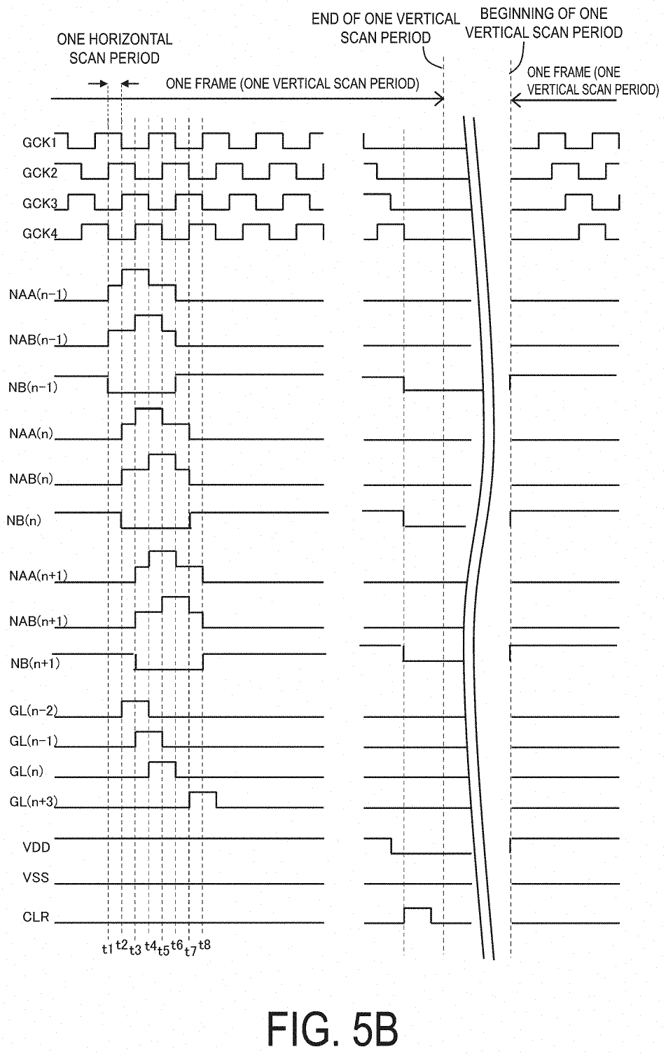

FIG. 5A is a circuit diagram illustrating the basic unit circuit Uref(n). FIG. 5B is a signal waveform diagram (timing chart) for describing operations of the gate driver GD.

As described above, the basic unit circuit Uref(n) includes one bistable circuit SR(n) and buffer circuits Buff(n−1) and Buff(n). The bistable circuit SR(n) includes a plurality of thin film transistors M1, M2, M3, M5, M6, M6+, M9, and M14. The buffer circuit Buff(n−1) includes a buffer transistor M1OA and a boost capacitor CbsA. The buffer circuit Buff(n) includes a buffer transistor M10B a boost capacitor CbsB, and a transistor MS. In this example, transistors M1, M2, M3, M5, M6, M6+, M9, M10A, M10B, M14, and MS are n-channel type TFTs.

The basic unit circuit Uref(n) also includes terminals to which two gate clock signals (first and fourth gate clock signals GCK1 and GCK4 in this example) are input, a clear terminal to which the clear signal CLR is input, a VDD terminal and a VSS terminal to which the power supply voltage signals (VDD and VSS) are input (connected to the power supply line), respectively, a set terminal to which a set signal S is input, a reset terminal to which a reset signal R is input, a first node NAA(n), a second node NB(n), and a third node NAB(n).

A signal (scanning signal) output from a stage preceding this unit circuit is input as the set signal S to the set terminal, and a signal output from a stage subsequent to this unit circuit is input as the reset signal R to the reset terminal. In this example, the scanning signal G(n−2) supplied to the gate bus line GL(n−2) is input, as the set signal S, to the set terminal. The scanning signal G(n+3) supplied to the gate bus line GL(n+3) is input, as the reset signal R, to the reset terminal. Note that the gate start pulse signals GSP1 and GSP2 are input, as the set signals S, from the controller to the set terminals of the unit circuits U(1) and U(2) in the first stages of the first and second gate drivers 410 and 420, respectively.

In the bistable circuit SR(n), a gate electrode of the transistor M1 is connected to the set terminal, and a drain electrode is connected to the VDD terminal (high-level power supply line). A gate electrode of the transistor M9 is connected to the reset terminal, and a source electrode is connected to the VSS terminal (low-level power supply line). A source electrode of the transistor M1 and a drain electrode of the transistor M9 are connected to each other, and this connection point corresponds to an output end of the bistable circuit SR(n). In the present specification, a node NAA(n) including the output end of the bistable circuit SR(n) is referred to as a “first node”. When an active signal (high-level signal) is supplied, as the set signal S, to the set terminal, the voltage of the first node NAA(n) is at the high-level, and the bistable circuit SR(n) is in a set state. On the other hand, when an active signal (high-level signal) is supplied, as the reset signal R, to the reset terminal, the voltage of the first node NAA(n) is at the low-level, and the bistable circuit SR(n) is in a reset state.

The transistor M14 is connected to the gate bus line GL(n) corresponding to this bistable circuit SR(n). A source electrode and a drain electrode of the transistor M14 are connected to the VSS terminal and the gate bus line GL(n), respectively. The node NB(n) connected to a gate electrode of the transistor M14 is referred to as a “second node”.

A gate electrode, a source electrode, and a drain electrode of the transistor M2 are connected to the clear terminal, the VSS terminal, and the first node NAA(n), respectively.

A gate electrode, a source electrode, and a drain electrode of the transistor M3 are connected to the clear terminal, the VSS terminal, and the second node NB(n), respectively.

A gate electrode and a drain electrode of the transistor M5 are connected to the VDD terminal, and a source electrode is connected to the second node NB(n).

A gate electrode, a source electrode, and a drain electrode of the transistor M6+ are connected to the set terminal, the VSS terminal, and the second node NB(n), respectively.

A gate electrode, a source electrode, and a drain electrode of the transistor M6 are connected to the node NAA(n), the VSS terminal, and the second node NB(n), respectively.

A gate electrode, a source electrode, and a drain electrode of the transistor M8 are connected to the second node NB(n), the VSS terminal, and the first node NAA(n), respectively.

In the buffer circuit Buff(n−1), a gate electrode, a drain electrode, and a source electrode of the buffer transistor M1OA are connected to the first node NAA(n), an input terminal to which the gate clock signal (here, the fourth gate clock signal GCK4) is input, and the gate bus line GL(n−1), respectively.

In the buffer circuit Buff(n), a gate electrode, a drain electrode, and a source electrode of the buffer transistor M10B are connected to the first node NAA(n) via the transistor MS, an input terminal to which the gate clock signal (here, the first gate clock signal GCK1) is input, and the gate bus line GL(n), respectively. The node NAB(n) connected to the gate electrode and the transistor MS of the buffer transistor M10B is referred to as a “third node”. The transistor MS has a function of suppressing an influence of a boost effect on one node to the other node between the first node NAA(n) and the third node NAB(n).

Next, an example of operations of the gate driver GD will be described with reference to FIGS. 4, 5A, and 5B.

The first to fourth gate clock signals GCK1 to GCK4 periodically repeat the high-level potential and the low-level potential in a predetermined cycle. The high-level potential is, for example, the same potential as the power supply voltage signal VDD, and the low-level potential is, for example, the same potential as the power supply voltage signal VSS. The first and third gate clock signals GCK1 and GCK3 have phases opposite to each other, and the second and fourth gate clock signals GCK2 and GCK4 have phases opposite to each other. The phases of the gate clock signals GCK1, GCK2, and GCK4 are shifted from each other by one horizontal scan period, and the phases of the gate clock signals GCK3, GCK2, and GCK4 are shifted from each other by one horizontal scan period. In other words, in this example, each of the gate clock signals GCK1 to GCK4 repeats the high-level potential and the low-level potential for each two horizontal scan periods.

The clear signal CLR is a signal for initializing the shift register. The clear signal is a signal that is at the high-level potential only during two horizontal scan periods and at the low-level potential during the other periods for each one vertical scan period.

First, a signal which is at the high-level only during a predetermined period at the time of activation of the display device is supplied, as an initialization signal, to the clear terminal of the bistable circuit SR(i) (i: an integer from 1 to N) in each unit circuit U(i) of the gate driver GD. As a result, voltages of the first node NAA(i), the third node NAB(i), and the second node NB(i) in each unit circuit is at the low-level.

At a point in time t2 after the initialization, the voltage of the gate bus line GL(n−2) connected to the set terminal of the bistable circuit SR(n) of the first gate driver 410 changes from the low-level to the high-level. Thus, the transistor M1 for the set of bistable circuit SR(n) changes to the on state, and the first node NAA(n) is pre-charged to the high-level (this high-level is lower than the potential of the high-level power supply voltage signal VDD by a threshold voltage Vth (M1) of the transistor M1). As a result, the third node NAB(n) is also pre-charged to the high-level. Here, since a threshold voltage Vth (MS) of the transistor MS is higher than the threshold voltage Vth (M1) of the transistor M1, this high-level is lower than the potential of the high-level power supply voltage signal VDD by the threshold voltage Vth (MS) of the transistor MS.

At a point in time t3, the fourth gate clock signal GCK4 changes from the low-level to the high-level. As a result, in the first output buffer unit 412, charging of the gate bus line GL(n−1) via the buffer transistor M1OA is started. At this time, the voltage change of the gate bus line GL(n−1) pushes up the voltage of the first node NAA(n) via the boost capacitor CbsA, and thus a voltage sufficiently higher than the normal high-level is applied to a gate terminal of the buffer transistor M1OA. As a result, the transistor M1OA is completely at the on state, and the gate bus line GL(n−1) is charged to the complete high-level from one end side (left side in FIG. 4). At this time, also in the buffer circuit Buff(n−1) in the second output buffer unit 422, a transistor M10B is at the complete on state, and the gate bus line GL(n−1) is charged to the complete high-level also from the other end side (right side in FIG. 4).

At a point in time t4, the first gate clock signal GCK1 changes from the low-level to the high-level. As a result, charging of the gate bus line GL(n) via the buffer transistor M10B is started. At this time, the voltage change of the gate bus line GL(n) pushes up the voltage of the third node NAB(n) via the boost capacitor CbsB, and thus a voltage sufficiently higher than the normal high-level is applied to the gate terminal of the buffer transistor M10B. As a result, the transistor M10B is completely at the on state, and the gate bus line GL(n) is charged to the complete high-level from one end side (left side in FIG. 4). At this time, also in the buffer circuit Buff(n) in the second output buffer unit 422, a transistor M1OA is at the complete on state, and the gate bus line GL(n) is charged to the complete high-level also from the other end side (right side in FIG. 4).

At a point in time t5, the fourth gate clock signal GCK4 changes from the high-level to the low-level. Thus, the charge of the gate bus line GL(n−1) is discharged via the buffer transistor M10A in the buffer circuit Buff(n−1) of the first output buffer unit 412 and the buffer transistor M10B in the buffer circuit Buff(n−1) of the second output buffer unit 422. As a result, the voltage of the gate bus line GL(n−1) changes to the low-level (that is, changes to a non-select state) at a higher speed.

At a point in time t16, the first gate clock signal GCK1 changes from the high-level to the low-level. Thus, similar to the above description, the charge of the gate bus line GL(n) is discharged via the buffer transistors M10B and M10A in the buffer circuits Buff(n) of the first and second output buffer units 412 and 422, respectively. As a result, the voltage of the gate bus line GL(n) changes to the low level at a higher speed. In this way, the gate bus line GL(n) is at a select state at the point in time t4 and changes to the non-select state at the point in time t6.

Although not illustrated, the gate bus line GL(n+1) is at the select state at the point in time t5 due to similar charging and discharging by two buffer circuits Buff(n+1) connected to both ends of the gate bus line GL(n+1), and changes to the non-select state at the point in time t7. Similarly, the gate bus line GL(n+2) is at the select state at the point in time t6, and changes to the non-select state at the point in time t8. The gate bus line GL(n+3) changes from the low-level to the high-level at the point in time t7.

At the point in time t7, when the voltage of the gate bus line GL(n+3) changes to the high-level, the high-level is supplied to the reset terminal and the transistor M9 changes to the on state in the bistable circuit (n) in FIG. 5A. As a result, the charge of the first node NAA(n) is discharged, and the voltage of the first node NAA(n) changes to the low-level. At this time, the charge of the third node NAB(n) is also discharged via the transistor MS, and the voltage of the third node NAB(n) is also changed to the low-level. As a result, the bistable circuit SR(n) is in the reset state. On the other hand, the node NB(n) is connected to the VDD terminal (high-level power supply line) via the transistor M5 in a diode-connected state, and thus when the transistor M6 changes to the off state by the transistor M9 changing to the on state at the point in time t7, the node NB(n) changes to the high-level. As a result, the transistor M8 changes to the on state, and the low-level power supply voltage signal VSS is supplied to the first node NAA(n). This works toward maintaining the first node NAA(n) at the low-level, while turning off the transistor M6 to maintain the second node NB(n) at the high-level. In this manner, until the transistor M1 is at the on state by changing the voltage of an (n−2)th gate bus line GL(n−2) to the high-level in the next frame period, the first node NAA(n) is reliably maintained at the low-level and the second node NB(n) is reliably maintained at the high-level.

According to the gate driver GD configured as described above, in the first gate driver 410, the first gate start pulse signal GSP1 included in the first scanning side control signal GCT1 is supplied to the bistable circuit SR(1) in the first stage in the first shift register 411, and is sequentially transferred to the cascade-connected bistable circuits based on the first to fourth gate clock signals GCK1 to GCK4. Similarly, in the second gate driver 420, the second gate start pulse signal GSP2 included in the second scanning side control signal GCT2 is supplied to the bistable circuit SR(2) in the first stage in the second shift register 421, and is sequentially transferred to the cascade-connected bistable circuits based on the first to fourth gate clock signals GCK1 to GCK4. In other words, the cascade-connected bistable circuits in the first shift register 411 and in the second shift register 421 sequentially output active signals (high-level signals including a level after the boost operation). In response to this, a high-level or a low-level voltage corresponding to each of the scanning signals G(1) to G(N) is applied to both ends of a respective one of the gate bus lines GL(1) to GL(N) by the buffer circuits of the first and second output buffer units 412 and 422. As a result, the gate bus lines GL(1) to GL(N) are sequentially at the select state (high-level) for a predetermined period of time.

### Configuration of Unit Circuit U including Four-Terminal Structure TFT

In the active matrix substrate 100 of the present embodiment, the gate driver GD includes at least one unit circuit (or bistable circuit) including the four-terminal structure TFT. This unit circuit has a configuration in which the two TFTs included in the basic unit circuit Uref illustrated in FIG. 5A are replaced with the four-terminal structure TFT. The four-terminal structure TFT corresponds to the first TFT described with reference to FIGS. 1A and 1B. That is, the four-terminal structure TFT includes two gate electrodes (a lower gate electrode and an upper gate electrode) located on a side of the substrate of the semiconductor layer and on a side opposite thereto.

Among the plurality of TFTs constituting the basic unit circuit Uref illustrated in FIG. 5A, combinations of the two TFTs satisfying the conditions (A) to (C) described above and capable of being replaced with the four-terminal structure TFT is illustrated below.
(a) The transistor M3 and the transistor M6
(b) The transistor M3 and the transistor M6+
(c) The transistor M2 and the transistor M8
(d) The transistor M2 and the transistor M9

Accordingly, the gate driver GD of the present embodiment includes at least one unit circuit in which at least one set of above-described (a) to (d) is replaced with the four-terminal structure TFT. The operations and the signal waveforms of the gate driver GD are similar to the operations and the signal waveforms described above with reference to FIG. 5B.

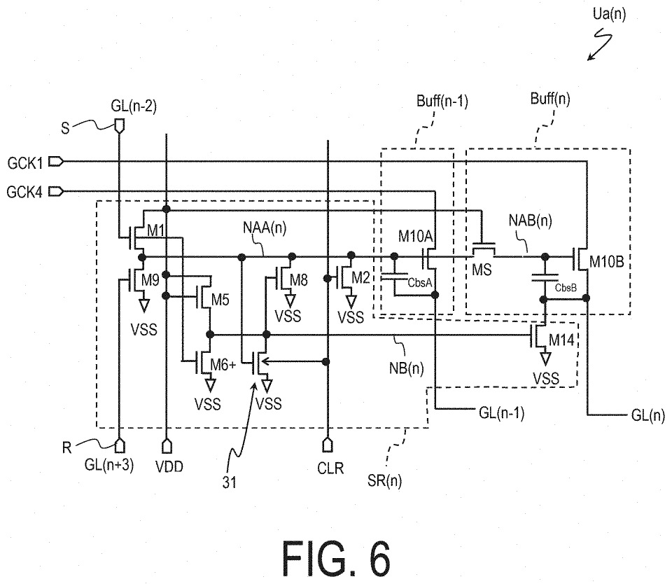

Each of FIGS. 6 to 10 is a circuit diagram illustrating a configuration of a respective one of unit circuits Ua(n) to Ue(n) according to the present embodiment. These unit circuits Ua(n) to Ue(n) have the same function as the basic unit circuit Uref(n) described above with reference to FIG. 5A, and can operate in the same manner.

The unit circuit Ua(n) illustrated in FIG. 6 differs from the basic unit circuit Uref(n) in that a four-terminal structure TFT 31 including a back gate is included in place of the transistors M3 and M6.

In the unit circuit Ua(n), a source electrode and a drain electrode of the four-terminal structure TFT 31 are connected to the VSS terminal, and the second node NB(n), respectively. Furthermore, one of the lower gate electrode and the upper gate electrode of the four-terminal structure TFT 31 is connected to the first node NAA(n) and the other is connected to the clear terminal.

As described above, in a case where the four-terminal structure TFT 31 including the upper gate insulating layer thinner than the lower gate insulating layer is used, it is preferable to supply a signal applied to the gate of a TFT, which requires further higher mobility (that is, further higher speed operation), among the two TFTs that can be replaced, to the upper gate electrode of the four-terminal structure TFT 31. Here, the transistor M6 has a function of lowering the second node NB(n), and the transistor M3 has a function of lowering the second node NB(n) at a timing when the clear signal CLR is at the high-level. In these two functions, the function of lowering the second node NB(n) is more important, and lowering at a higher speed is required. On the other hand, the transistor M3 is not required to operate at a higher speed as the transistor M6. This is because as for the clear signal CLR, for example, it is also possible to increase the time at the high-level and lower the second node NB(n), and thus the priority of reducing the lowering time is low. Thus, it is preferable that the upper gate electrode and the lower gate electrode of the four-terminal structure TFT 31 are connected to the first node NAA(n), and the clear terminal, respectively. As a result, the second node NB(n) can be lowered at a further higher speed while suppressing an increase in the size (channel width) of the four-terminal structure TFT 31.

As can be seen from FIG. 5B, the clear signal CLR is at the low-level during the points in time t1 to t6 when the first node NAA(n) is at the high-level, and the first node NAA(n) is at the low-level in a period during which the clear signal CLR is at the high-level (before the start of each frame). Accordingly, the four-terminal structure TFT 31 functions as the transistor M6 of the basic unit circuit Uref in a period during which the first node NAA(n) is at the high-level, and functions as the transistor M3 of the basic unit circuit Uref in the period during which the clear signal CLR is at the high-level (before the start of each frame).

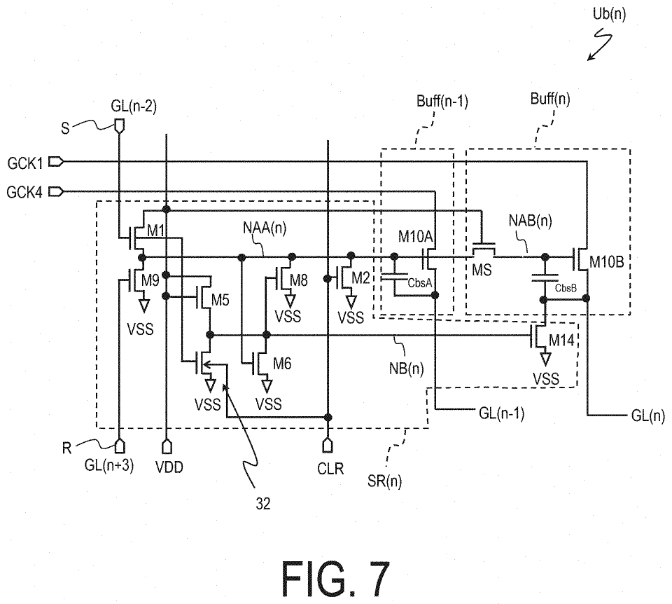

The unit circuit Ub(n) illustrated in FIG. 7 differs from the basic unit circuit Uref(n) in that a four-terminal structure TFT 32 including a back gate is included in place of the transistors M3 and M6+.

In the unit circuit Ub(n), a source electrode and a drain electrode of the four-terminal structure TFT 32 are connected to the VSS terminal, and the second node NB(n), respectively. Furthermore, one of the upper gate electrode and the lower gate electrode of the four-terminal structure TFT 32 is connected to the set terminal and the other is connected to the clear terminal. As described above, the set terminal of the unit circuit Ub(n) (n: three or more) is connected to the gate bus line GL(n−2), and the gate start pulse signals GSP1 and GSP2 are supplied, as the set signals S, to the set terminals of the unit circuits Ub(1) and Ub(2), respectively.

For example, it is preferable that the upper gate electrode is connected to the set terminal, and the lower gate electrode is connected to the clear terminal. As a result, the second node NB(n) can be lowered at a further higher speed while suppressing an increase in the size (channel width) of the four-terminal structure TFT 32. This reason for this is the same as that described in the unit circuit Ua(n).

As can be seen from FIG. 5B, in the unit circuit Ub(n) (n: three or more), the clear signal CLR is at the low-level during the points in time t2 to t4 when the gate bus line GL(n−2) is at the high-level, and the gate bus line GL(n−2) is at the low-level in a period during which the clear signal CLR is at the high-level (before the start of each frame). Accordingly, the four-terminal structure TFT 32 functions as the transistor M6+ of the basic unit circuit Uref in a period during which the gate bus line GL(n−2) is at the high-level, and functions as the transistor M3 of the basic unit circuit Uref in a period during which the clear signal CLR is at the high-level (before the start of each frame).

Although not illustrated, even in the unit circuits Ub(1) and Ub(2) in the first stage, periods at the high-level do not overlap each other between the gate start pulse signals GSP1 and GSP2 supplied to the set terminals and the clear signals CLR, and thus the same effect can be obtained.

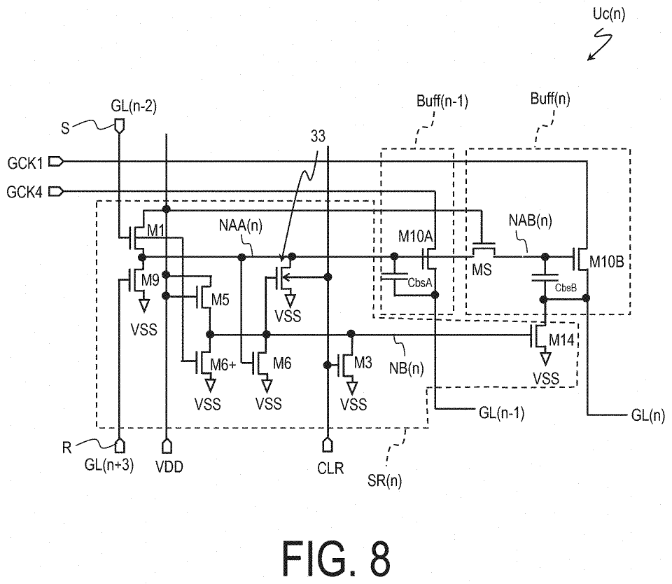

The unit circuit Uc(n) illustrated in FIG. 8 differs from the basic unit circuit Uref(n) in that a four-terminal structure TFT 33 including a back gate is included in place of the transistors M2 and M8.

In the unit circuit Uc(n), a source electrode and a drain electrode of the four-terminal structure TFT 33 are connected to the VSS terminal, and the first node NAA(n), respectively. Furthermore, one of the upper gate electrode and the lower gate electrode of the four-terminal structure TFT 33 is connected to the second node NB(n) and the other is connected to the clear terminal.

It is preferable to supply a signal applied to the gate of a TFT (here, transistor M8) which requires further higher mobility (that is, further higher speed operation) among the two transistors M2 and M8 of the basic unit circuit Uref to the upper gate electrode of the four-terminal structure TFT 33. Thus, it is preferable that, for example, the upper gate electrode and the lower gate electrode of the four-terminal structure TFT 33 are connected to the second node NB(n), and the clear terminal, respectively. As a result, the first node NAA(n) can be further reliably stabilized at the lower-level while suppressing an increase in the size (channel width) of the four-terminal structure TFT 33.

As can be seen from FIG. 5B, the clear signal CLR is at the low-level in the period during which the second node NB(n) is at the high-level, and the second node NB(n) is at the low-level in the period during which the clear signal CLR is at the high-level (before the start of each frame). Accordingly, the four-terminal structure TFT 33 functions as the transistor M8 of the basic unit circuit Uref in a period during which the second node NB(n) is at the high-level, and functions as the transistor M2 of the basic unit circuit Uref in a period during which the clear signal CLR is at the high-level (before the start of each frame).

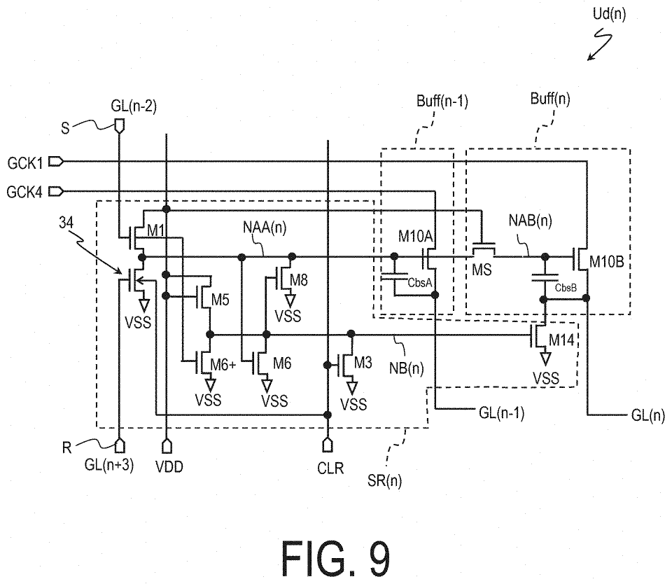

The unit circuit Ud(n) illustrated in FIG. 9 differs from the basic unit circuit Uref(n) in that a four-terminal structure TFT 34 including a back gate is included in place of the transistors M2 and M9.

In the unit circuit Ud(n), a source electrode and a drain electrode of the four-terminal structure TFT 34 are connected to the VSS terminal, and the first node NAA(n), respectively. Furthermore, one of the upper gate electrode and the lower gate electrode of the four-terminal structure TFT 34 is connected to the reset terminal and the other is connected to the clear terminal. As described above, in the unit circuits Ud(n) (n:1 to N−3), the reset terminal is connected to the gate bus line GL(n+3), and in the unit circuits Ud(N−2), Ud(N−1), and Ud(N), the clear signal CLR is supplied, as the reset signal R, to the reset terminal.

It is preferable to supply a signal applied to the gate of a TFT (here, transistor M9) which requires further higher mobility (that is, further higher speed operation) among the two transistors M2 and M9 of the basic unit circuit Uref to the upper gate electrode of the four-terminal structure TFT 34. Thus, it is preferable that, for example, the upper gate electrode and the lower gate electrode of the four-terminal structure TFT 34 are connected to the reset terminal, and the clear terminal, respectively.

As can be seen from FIG. 5B, in the unit circuit Ud(n) (n:1 to N−3), the clear signal CLR is at the low-level in a period during which the gate bus line GL(n+3) is at the high-level, and the gate bus line GL(n+3) is at the low-level in a period during which the clear signal CLR is at the high-level (before the start of each frame). Accordingly, the four-terminal structure TFT 34 functions as the transistor M9 of the basic unit circuit Uref in a period during which the gate bus line GL(n+3) is at the high-level, and functions as the transistor M2 in a period during which the clear signal CLR is at the high-level (before the start of each frame).

Although not illustrated, in three unit circuits Ud(N−2), Ud(N−1), and Ud(N) in the final stage, the clear signal CLR is supplied to the reset terminal. Thus, the same signal (clear signal CLR) is supplied to the gate electrode of the transistors M2 and M9, and the transistors M2 and M9 do not satisfy the conditions (B) and (C) described above. Thus, in the three unit circuits in the final stage, the transistors M2 and M9 are not replaced with one four-terminal structure TFT. That is, the number of TFTs increases to more than that of the other unit circuits. These unit circuits may have the same configuration as the basic unit circuit Uref illustrated in FIG. 5A. In this way, for example, some unit circuits including the unit circuits in the final stage may have a similar configuration to the basic unit circuit as illustrated in FIG. 5A, and some other unit circuits may have a configuration including the four-terminal structure TFT as illustrated in FIG. 9.

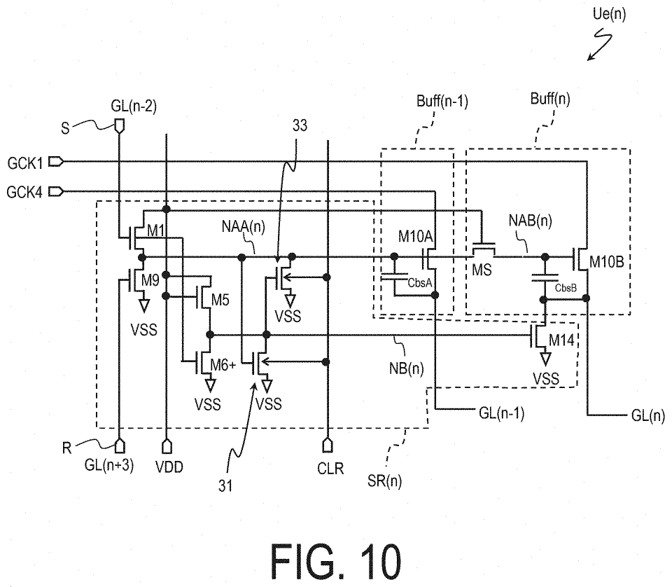

The unit circuit in the present embodiment may include two or more four-terminal structures TFT. Here, one four-terminal structure TFT corresponding to a combination of (a) or (b) in the basic unit circuit Uref and one other four-terminal structure TFT corresponding to a combination of (c) or (d) may be included. For example, as illustrated in FIG. 10, the unit circuit Ue(n) may include the four-terminal structure TFT 31 in place of transistors M3 and M6 of the basic unit circuit Uref, and may include the four-terminal structure TFT 33 in place of transistors M2 and M8 of the basic unit circuit Uref.

In the semiconductor device of the present embodiment, all unit circuits (or bistable circuits) constituting the gate driver GD may include at least one of the four-terminal structures TFT 31 to 34 described above. As a result, the effect of reducing the circuit area can be more prominently obtained.

Alternatively, some unit circuits constituting the gate driver GD may be the unit circuits Ua to Ue including at least one of the four-terminal structures TFT 31 to 34 as illustrated in FIGS. 6 to 10, and some other unit circuits may be the basic unit circuit Uref illustrated in FIG. 5A. For example, the plurality of bistable circuits SR(n) constituting the shift registers 411 and 421 may include a first bistable circuit including at least one four-terminal structure TFT having the configuration described above, and a second bistable circuit not including such a four-terminal structure TFT (for example, having a configuration similar to that of the bistable circuit SR(n) of the basic unit circuit Uref(n)). In the first bistable circuit, since two TFTs among the plurality of TFTs constituting the second bistable circuit are replaced with the one four-terminal structure TFT, the number of TFTs constituting the first bistable circuit is less than the number of TFTs constituting the second bistable circuit.

The configuration and operation of the gate driver to which the four-terminal structure TFT of the present embodiment are applied are not limited to the above-described examples. A specific configuration of the unit circuit included in the gate driver is disclosed, for example, in US 2020/0135132, JP 2019-74560 A, WO 2014/061574, or the like by the present applicant. For reference, the entire contents of the disclosures of US 2020/0135132, JP 2019-74560 A, WO 2014/061574, are incorporated herein. The terminals and nodes connecting the four-terminal structure TFT, the waveforms of signals applied to the upper gate electrode and the lower gate electrode, and the like are not particularly limited.

Note that the four-terminal structure TFT of the present embodiment may also be applied to a circuit other than the gate driver. Regardless of the type, application, or the like of the circuit, the circuit area can be reduced by providing one four-terminal structure TFT in place of the two TFTs satisfying the above-described predetermined conditions (A) to (C) among a plurality of TFTs constituting a basic circuit.

### First Modified Example: Protection Circuit

In a first modified example, an example will be described in which the four-terminal structure TFT in the present embodiment is applied to a protection circuit such as a diode ring.

In a semiconductor device such as an active matrix substrate, a diode ring with two diodes parallel in opposite directions may be provided between two wiring lines as an Electro-Static Discharge (ESD) protection circuit to prevent damage of an element, a wiring line, and the like due to static electricity. As the two diodes constituting the diode ring, for example, a diode (hereinafter, referred to as a TFT type diode) obtained by short circuiting a gate and a source or a gate and drain of a TFT may be used.

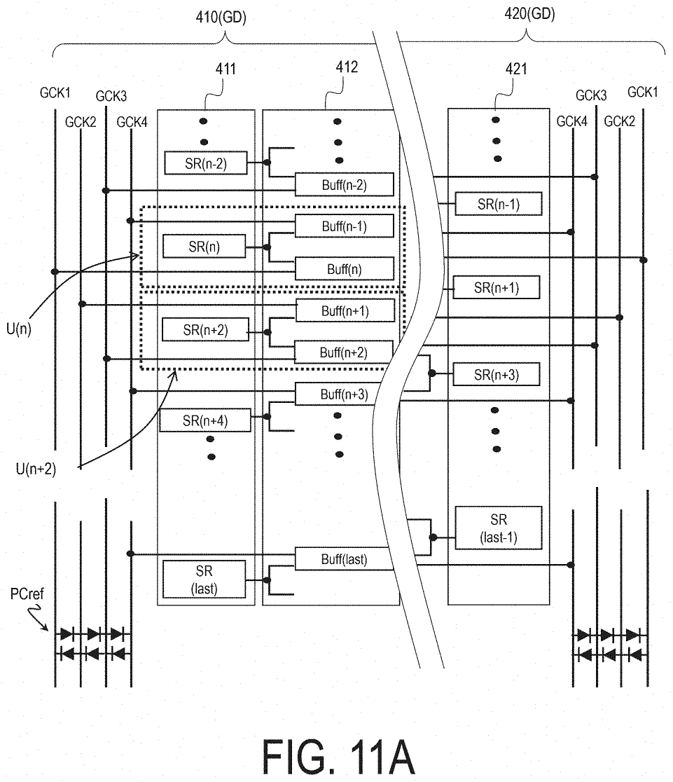

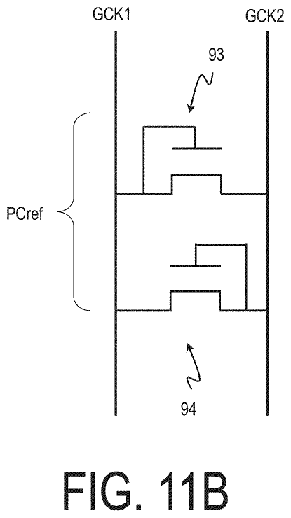

FIG. 11A is a diagram illustrating a semiconductor device (here, active matrix substrate) including a protection circuit PCref of a reference example. In this example, the protection circuit PCref is provided between each two signal wiring lines adjacent to each other among the plurality of signal wiring lines that supply the gate clock signals GCK1 to GCK4 to the gate driver GD. Each protection circuit PCref is the diode ring including two diodes.

FIG. 11B is a circuit diagram of the protection circuit PCref of the reference example. The protection circuit PCref includes two TFT type diodes 93 and 94. The TFT type diodes 93 and 94 are connected in parallel in opposite directions to each other between two wiring lines (in this example, wiring lines that supply the gate clock signals GCK1 and GCK2).

The TFT type diodes 93 and 94 satisfy the predetermined conditions (A) to (C), and thus they can be replaced with one four-terminal structure TFT.

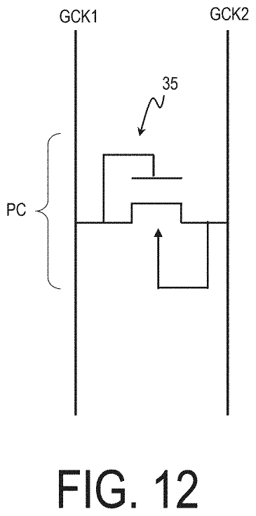

FIG. 12 is a diagram illustrating an example of a protection circuit PC according to the present modified example. As illustrated in FIG. 12, the protection circuit PC includes a four-terminal structure TFT 35 disposed between two wiring lines. In this example, the source electrode and the drain electrode of the four-terminal structure TFT 35 are connected to a first signal wiring line that supplies the gate clock signal GCK1 and a second signal wiring line that supplies the gate clock signal GCK2, respectively. One of the two gate electrodes (upper gate electrode and the lower gate electrode) of the four-terminal structure TFT 35 is connected to the first signal wiring line and the other is connected to the second signal wiring line.

According to the present embodiment, the protection circuit PC can be obtained in which the circuit area is reduced by reducing the number of TFTs to less than that in the reference example, while having a function similar to that of the protection circuit PCref of the reference example including the two TFT type diodes 93 and 94.

Note that the wiring line connected to the protection circuit PC is not limited to the gate clock signal wiring line. The present modified example is applicable to various circuits and semiconductor devices in which the protection circuit can be provided.

### Second Modified Example: Demultiplexer Circuit

In a second modified example, an example will be described in which the four-terminal structure TFT in the present embodiment is applied to a demultiplexer circuit.

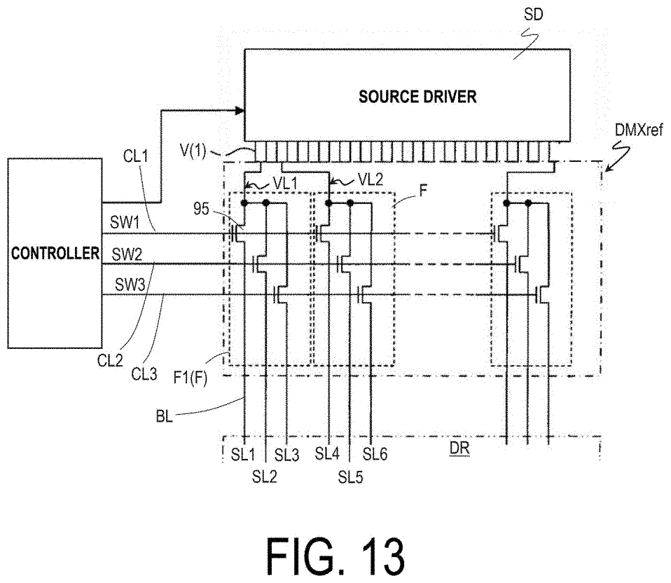

FIG. 13 is a diagram illustrating an example of a demultiplexer circuit DMXref of the reference example. The demultiplexer circuit DMXref is integrally (monolithically) provided on the active matrix substrate. The demultiplexer circuit DMXref is disposed, for example between the source driver SD and the display region DR. The demultiplexer circuit DMXref includes a plurality of TFTs 95.

The demultiplexer circuit DMXref includes a plurality of unit circuits F supported by the substrate 1. Each of the plurality of unit circuits F distributes a display signal from one signal output line VL to a plurality (three in this example) of the source bus lines SL.

Each unit circuit F includes a plurality (three in this example) of branch wiring lines BL and a plurality (here, three) of TFTs 95. Three branch wiring lines BL are connected to the one signal output line VL. Each TFT 95 is connected to one corresponding branch wiring line BL. Each of these TFTs 95 individually (independently) on/off controls the electrical connections between a respective one of the three branch wiring lines BL and a respective one of the three source bus lines SL.

The demultiplexer circuit DMXref also includes a plurality (here, three) of control signal trunk lines CL1 to CL3 (collectively referred to as “control signal trunk lines CL”). The control signal trunk lines CL are connected to a controller provided in the non-display region FR.

Hereinafter, the configuration of each unit circuit F will be described more specifically taking a unit circuit F1 as an example.

The unit circuit F1 distributes a display signal V(1) from signal output line VL1 to source bus lines SL1 to SL3. A source electrode and a drain electrode of each TFT 95 in the unit circuit F1 are connected to a corresponding branch wiring line BL and source bus line SL, respectively to on/off control electrical connection between the corresponding branch wiring line BL and source bus line SL. Each of selection signals (DMX control signals) SW1 to SW3 is supplied from a respective one of the control signal trunk lines CL1 to CL3 to a gate electrode of a respective one of TFTs 95. These DMX control signals SW1 to SW3 define on-periods of the selection switches within the same group and are synchronized with time-sequential signals output from the source driver SD. Each unit circuit F writes a data potential obtained by time-dividing the output of the signal output line VL to the corresponding three source bus lines SL time-sequentially (time division driving). For reference in the present specification, as for the action, the timing chart of the time division driving, and the like of the display device using the demultiplexer circuit, the entire contents of the disclosure of JP 2008-225036 A, JP 2006-119404 A, and WO 2011/118079 are incorporated herein by reference.

In the present modified example, the four-terminal structure TFT is used in place of each TFT 95. For example, each unit circuit F may include three four-terminal structures TFT.

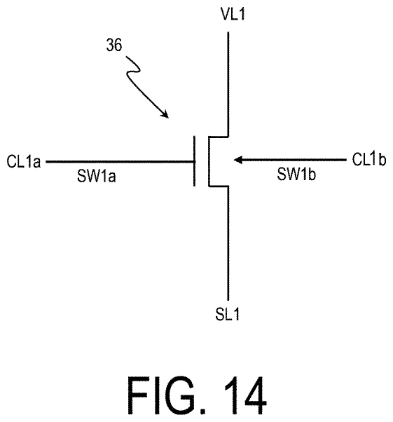

FIG. 14 is a diagram illustrating one four-terminal structure TFT 36 in the unit circuit F1. Here, a source electrode and a drain electrode of the four-terminal structure TFT 36 are connected to the signal output line VL1 and the source bus line SL1, respectively. Two gate electrodes (upper gate electrode and lower gate electrode) of the four-terminal structure TFT 36 are connected to control signal wiring lines CL1a and CL1b, respectively, different from each other. A DMX control signal SW1a is supplied to one of the two gate electrodes via the control signal wiring line CL1a, and a DMX control signal SW1b is supplied to the other via the control signal wiring line CL1b. The two DMX control signals SW1a and SW1b may be configured to be, for example, alternately at the high-level potential for each frame. By causing potentials of the two gate electrodes to be alternately at the high-level for each frame to drive the four-terminal structure TFT 36, the effect of reducing the shift of the threshold voltage Vth can be obtained.

### Oxide Semiconductor

When the semiconductor layer 7 of the first TFT 30 is an oxide semiconductor layer, the oxide semiconductor layer 7 may be an amorphous oxide semiconductor, or may be a crystalline oxide semiconductor including a crystalline portion. Examples of the crystalline oxide semiconductor include a polycrystalline oxide semiconductor, a microcrystalline oxide semiconductor, a crystalline oxide semiconductor having a c-axis oriented substantially perpendicular to the layer surface and the like.

The oxide semiconductor layer 7 may have a layered structure including two or more layers. When the oxide semiconductor layer 7 has the layered structure, the oxide semiconductor layer 7 may include an amorphous oxide semiconductor layer and a crystalline oxide semiconductor layer. Alternatively, the oxide semiconductor layer may include a plurality of crystalline oxide semiconductor layers having different crystal structures. The oxide semiconductor layer may include a plurality of amorphous oxide semiconductor layers. When the oxide semiconductor layer 7 has a dual-layer structure including an upper layer and a lower layer, an energy gap of the oxide semiconductor included in the upper layer is preferably greater than an energy gap of the oxide semiconductor included in the lower layer. However, when a difference in the energy gap between these layers is relatively small, the energy gap of the oxide semiconductor in the lower layer may be greater than the energy gap of the oxide semiconductor in the upper layer.

Materials, structures, and film formation methods of an amorphous oxide semiconductor and the above-described crystalline oxide semiconductors, a configuration of an oxide semiconductor layer having a layered structure, and the like are described in, for example, JP 2014-007399 A. The entire contents of the disclosure of JP 2014-007399 A are incorporated herein by reference.

The oxide semiconductor layer 7 may include, for example, at least one metal element selected from In, Ga, and Zn. In the present embodiment, the oxide semiconductor layer 7 includes, for example, an In—Ga—Zn—O based semiconductor (for example, an indium gallium zinc oxide). Here, the In—Ga—Zn—O based semiconductor is a ternary oxide of indium (In), gallium (Ga), and zinc (Zn), and a ratio (composition ratio) of In, Ga, and Zn is not particularly limited. For example, the ratio includes In:Ga:Zn=2:2:1, In:Ga:Zn=1:1:1, In:Ga:Zn=1:1:2 or the like. Such an oxide semiconductor layer 7 can be formed of an oxide semiconductor film including an In—Ga—Zn—O based semiconductor.

The In—Ga—Zn—O based semiconductor may be an amorphous semiconductor or may be a crystalline semiconductor. A crystalline In—Ga—Zn—O based semiconductor in which a c-axis is oriented substantially perpendicular to a layer surface is preferable as the crystalline In—Ga—Zn—O based semiconductor.

Note that a crystal structure of the crystalline In—Ga—Zn—O based semiconductor is disclosed in, for example, JP 2014-007399 A, JP 2012-134475 A, and JP 2014-209727 A as described above. The entire contents of the disclosure of JP 2012-134475 A and JP 2014-209727 A are incorporated herein by reference. A TFT including an In—Ga—Zn—O based semiconductor layer has a high mobility (more than 20 times as compared to an a-Si TFT) and a low leakage current (less than 1/100 as compared to the a-Si TFT). Thus, such a TFT can be suitably used as a driving TFT (for example, a TFT included in a drive circuit provided in a periphery of a display region including a plurality of pixels, and on the same substrate as the display region) and a pixel TFT (TFT provided in a pixel).

In place of the In—Ga—Zn—O based semiconductor, the oxide semiconductor layer 7 may include another oxide semiconductor. For example, the oxide semiconductor layer may include an In—Sn—Zn—O based semiconductor (for example, In₂O₃—SnO₂—ZnO; InSnZnO). The In—Ga—Zn—O based semiconductor is a ternary oxide of indium (In), tin (Sn), and zinc (Zn). Alternatively, the oxide semiconductor layer 7 may include an In—W—Zn—O based semiconductor and an In—W—Sn—Zn—O based semiconductor containing tungsten (W), an In—Al—Zn—O based semiconductor, an In—Al—Sn—Zn—O based semiconductor, a Zn—O based semiconductor, an In—Zn—O based semiconductor, a Zn—Ti—O based semiconductor, a Cd—Ge—O based semiconductor, a Cd—Pb—O based semiconductor, CdO (cadmium oxide), a Mg—Zn—O based semiconductor, an In—Ga—Sn—O based semiconductor, an In—Ga—O based semiconductor, a Zr—In—Zn—O based semiconductor, a Hf—In—Zn—O based semiconductor, an Al—Ga—Zn—O based semiconductor, a Ga—Zn—O based semiconductor, an In—Ga—Zn—Sn—O based semiconductor, and the like.

The embodiments of the disclosure can be widely applied to various semiconductor devices provided with a circuit including a TFT. The embodiments are also applied to various electronic devices, including circuit substrates such as active matrix substrates, display devices such as liquid crystal display devices, organic electroluminescence (EL) display devices, inorganic electroluminescence display devices, and MEMS display devices, image taking devices such as image sensor devices, image input devices, fingerprint readers, semiconductor memories, and the like, for example.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. A semiconductor device comprising:
a substrate; and
a first circuit supported by the substrate,
wherein the first circuit includes a plurality of TFTs including a first TFT,
the first TFT includes
a semiconductor layer,
a lower gate electrode located on a side of the substrate of the semiconductor layer and overlapping a part of the semiconductor layer via a lower gate insulating layer, and
an upper gate electrode located on a side opposite to the substrate of the semiconductor layer and overlapping a part of the semiconductor layer via an upper gate insulating layer,
one of the lower gate electrode and the upper gate electrode is a first gate electrode and the other is a second gate electrode,
a first signal is supplied to the first gate electrode, and a second signal different from the first signal is supplied to the second gate electrode,
the first TFT has a threshold voltage at which the first TFT is switched on/off between a high-level potential and a low-level potential of the first signal and between a high-level potential and a low-level potential of the second signal, and
a period during which the first signal is at the high-level potential and a period during which the second signal is at the high-level potential do not overlap each other.

2. The semiconductor device according to claim 1, further comprising
a controller configured to supply at least one control signal to the first circuit,
wherein the controller controls the first circuit such that periods during which the first signal and the second signal are at a high-level potential do not overlap each other.

3. The semiconductor device according to claim 1,
wherein the plurality of TFTs further include a second TFT,
the second TFT includes
a second semiconductor layer,
a second lower gate electrode located on a side of the substrate of the second semiconductor layer and overlapping a part of the second semiconductor layer via the lower gate insulating layer, and
a second upper gate electrode located on a side opposite to the substrate of the semiconductor layer and overlapping a part of the second semiconductor layer via the upper gate insulating layer,
one of the second lower gate electrode and the second upper gate electrode is a third gate electrode and the other is a fourth gate electrode,
a third signal is supplied to the third gate electrode, a fourth signal different from the third signal is supplied to the fourth gate electrode, and at least one of the third signal and the fourth signal is different from any of the first signal and the second signal,
the second TFT has a threshold voltage at which the second TFT is switched on/off between a high-level potential and a low-level potential of the third signal and between a high-level potential and a low-level potential of the fourth signal, and
a period during which the third signal is at the high-level potential and a period during which the fourth signal is at the high-level potential do not overlap each other.

4. The semiconductor device according to claim 1,
wherein the semiconductor device includes a shift register including a plurality of bistable circuits connected in multiple stages, and
at least one of the plurality of bistable circuits includes the first circuit.

5. The semiconductor device according to claim 4,
wherein one of the first signal and the second signal is a clear signal configured to initialize the at least one bistable circuit.

6. The semiconductor device according to claim 4,
wherein the plurality of bistable circuits include a first bistable circuit including the first circuit, and a second bistable circuit not including the first circuit, and
the number of TFTs constituting the first bistable circuit is less than the number of TFTs constituting the second bistable circuit.

7. The semiconductor device according to claim 1, further comprising
a plurality of source bus lines and a plurality of gate bus lines supported by the substrate,
a plurality of pixel regions, each of which being arranged corresponding to one of the plurality of source bus lines and one of the plurality of gate bus lines, and
a gate driver configured to selectively drive the plurality of gate bus lines,
wherein the gate driver includes a shift register provided corresponding to the plurality of gate bus lines and including a plurality of bistable circuits connected in multiple stages to sequentially output pulses based on a plurality of gate clock signals having phases different from each other,
at least the plurality of gate clock signals, a high-level power supply voltage signal, a low-level power supply voltage signal, and a clear signal that initializes each bistable circuit are input to each bistable circuit, and
at least one of the plurality of bistable circuits includes the first circuit.

8. The semiconductor device according to claim 7,
wherein in the at least one bistable circuit, the low-level power supply voltage signal is supplied to a source electrode of the first TFT,
a drain electrode of the first TFT is connected to a first node including an output end of the at least one bistable circuit,
the clear signal is supplied to the first gate electrode, and
the second gate electrode is connected to a node different from the first node.

9. The semiconductor device according to claim 7,
wherein in the at least one bistable circuit, the low-level power supply voltage signal is supplied to a source electrode of the first TFT,
a drain electrode of the first TFT is connected to a first node including an output end of the at least one bistable circuit,
the clear signal is supplied to the first gate electrode, and
the second gate electrode is connected to a gate bus line corresponding to a bistable circuit in a stage subsequent to the at least one bistable circuit.

10. The semiconductor device according to claim 7,
wherein in the at least one bistable circuit, the low-level power supply voltage signal is supplied to a source electrode of the first TFT,
a drain electrode of the first TFT is connected to a second node different from a first node including an output end of the at least one bistable circuit,
the clear signal is supplied to the first gate electrode, and
the second gate electrode is connected to the first node.

11. The semiconductor device according to claim 7,
wherein in the at least one bistable circuit, the low-level power supply voltage signal is supplied to a source electrode of the first TFT,
a drain electrode of the first TFT is connected to a second node different from a first node including an output end of the at least one bistable circuit,
the clear signal is supplied to the first gate electrode, and
the second gate electrode is connected to a gate bus line corresponding to a bistable circuit in a stage preceding the at least one bistable circuit.

12. The semiconductor device according to claim 1,
wherein the first TFT is an oxide semiconductor TFT having an oxide semiconductor layer as an active layer.

13. The semiconductor device according to claim 12,
wherein the oxide semiconductor layer includes an In—Ga—Zn—O based semiconductor.

14. The semiconductor device according to claim 13,
wherein the In—Ga—Zn—O based semiconductor includes a crystalline portion.
